(19) United States
(12) Patent Application Publication
(10) Pub. No.: US 2016/0160098 A1
(43) Pub. Date: Jun. 9, 2016

(54) PHOTOCURABLE EPOXY ADHESIVE AGENT, RESIN COMPOSITION, LAMINATE , DISPLAY, AND METHOD FOR PRODUCING RESIN COMPOSITION

(71) Applicant: JNC CORPORATION, Tokyo (JP)

(72) Inventors: MAKOTO MITANI, CHIBA (JP); ATSUKO FUJITA, TOKYO (JP)

(21) Appl. No.: 14/781,038

(22) PCT Filed: Apr. 1, 2014
(86) PCT No.: PCT/JP2014/059664

§ 371 Date: Dec. 28, 2015

(30) Foreign Application Priority Data
Apr. 1, 2013 (JP) 2013-076249

(51) Int. Cl. C09J 163/00; C09J 11/04; H05B 33/04; H01L 51/00; B32B 7/12; G02F 1/1339; C09J 9/00; C09J 5/00

(52) U.S. Cl. CPC C09J 163/00; C09J 9/00; C09J 11/04; C09J 5/00; H01L 51/0034; B32B 7/12; G02F 1/1339; H05B 33/04; C08K 3/34

(57) ABSTRACT

The invention provides a photocuring epoxy adhesive agent having excellent polymerization conversion rate at low temperature, and excellent adhesive strength and resistance to moisture permeation, and also provides a cured product having good productivity. The photocuring epoxy adhesive agent of the invention contains: (A) an epoxy monomer or oligomer; (B) a photo cationic polymerization initiator; and (C) a layered silicate. Since the adhesive agent is photocurable, curing can be performed at low temperature, and the adhesive agent shows excellent adhesive strength. Moreover, since the adhesive agent can be cured in a short time, productivity is excellent. The cured resin composition has high resistance to moisture permeation.

### BACKGROUND OF THE INVENTION

1. Field of the Invention

The invention is related to a photocuring epoxy adhesive agent. More particularly, the invention is related to a photocuring epoxy adhesive agent having the advantage of low gas permeability.

2. Description of Related Art

As an adhesive agent used to adhering, for instance, may come in the form of two liquids in which a main agent and a curing agent are mixed before use and then cured to exhibit adhesive properties. On another front, a one-liquid type adhesive agent is via moisture curing or thermo curing, and these methods contain the possibility of slow moisture curing speed or product degradation due to heating in thermo curing.

Moreover, in the adhesive step of the products mass produced in the factory, an energy ray such as UV is irradiated or thermo energy is used out of necessity to shorten production tack-time, such that the adhesive agent is cured within a short time. As described above, good productivity is required for the adhesive agent.

When an energy ray such as UV is irradiated, the adhesive agent needs to sufficiently pass through UV. If the transmittance of UV is low, then the curing of the resin does not occur to the depth of the adhesive agent, and sufficient adhesive force can not be obtained.

Moreover, in a product sensitive to moisture, such as a liquid crystal display, an E-paper, or a solar cell panel, a component of the device is degraded due to permeation of water and oxygen in the device, and performance is reduced as a result. The adhesive agent used in the adhesive of such a device does not readily allow water vapor or reactive gas to pass through (resistance to moisture permeation). However, in normal adhesive agents, the gas permeability after curing, in particular water vapor permeability, is not low enough, which is therefore ineffective in terms of preventing degradation of the device. Therefore, in the adhesive agent for the device, an inorganic component referred to as a filler is generally added to prevent water permeation.

However, UV transmittance of a commonly used filler is low. Therefore, when the adhesive agent for the device is cured via UV irradiation, UV irradiation can only be performed on the surface, which is ineffective to the adhesive of the adhesive portions. As described above, regardless of whether the photocuring adhesive agent containing a filler preventing water permeation for the device contains a filler, the transmittance of, for instance, UV needs to be high and curing of the resin needs to reach the depth of the adhesive agent (high conversion rate).

Moreover, an acrylic resin has been used as the photocuring adhesive agent. Despite the advantages of using a plurality of acrylate monomers and oligomers, disadvantages of significant insufficiency of resistance to moisture permeation, large volume shrinkage, and insufficient adhesive strength are also present.

Known adhesive agents adopting other resins such as an epoxy resin include a thermosetting epoxy resin (such as patent literature 1). Patent literature 1 discloses a thermosetting epoxy resin containing mica of organic ammonium salt between layers to improve the dispersibility of the filler component used as the monomer of the adhesive agent component. However, for curing, heating needs to be performed.

### CURRENT TECHNICAL LITERATURE

### Patent Literature

Patent literature 1: Japanese Patent Publication No. 4112586

Therefore, a photocuring adhesive agent having good productivity is expected, which has high conversion rate in a lower temperature region, for instance, for preventing product degradation caused by heat. Moreover, the photocuring properties are excellent, and a cured product also having excellent adhesive properties with the substrate and resistance to moisture permeation is also expected.

### SUMMARY OF THE INVENTION

### Issue to be Solved by the Invention

The invention aims to solve the above issues caused by current techniques, and the issue is providing a photocuring adhesive agent having excellent polymerization conversion rate at low temperature, and providing a cured product not only having excellent adhesive strength and resistance to moisture permeation, but also having good productivity.

### Technical Means for Solving the Issues

To solve the issues, the Inventors conducted extensive studies and discovered that: the curability of the photocuring epoxy adhesive agent containing (A) an epoxy monomer or oligomer, (B) a photo cationic polymerization initiator, and (C) layered silicate at low temperature is excellent, and the cured product thereof not only has excellent adhesive strength and resistance to moisture permeation, but also has good productivity, thus completing the invention. Moreover, the Inventors also discovered that: such a photocurable resin composition is also suitable for a flat panel such as a liquid crystal display or an electroluminescent display.

The photocuring epoxy adhesive agent of the first embodiment of the invention contains: (A) an epoxy monomer or oligomer; (B) a photo cationic polymerization initiator; and (C) layered silicate.

If constructed in this manner, then the adhesive agent can be cured at low temperature due to the photocuring properties thereof. Moreover, the light transmittance of the layered silicate, such as UV transmittance, is high, the adhesive agent shows excellent adhesive strength via the curing properties thereof, and excellent resistance to moisture permeation is observed. Moreover, since the adhesive agent can be cured in a short time, productivity is excellent.

The photocuring epoxy adhesive agent of the second embodiment of the invention contains 100 parts by weight of (A) the epoxy monomer or oligomer and more than 100 parts by weight to 400 parts by weight of (C) the layered silicate in the photocuring epoxy adhesive agent of the first embodiment of the invention.

If constructed in this manner, then an adhesive agent having extremely low water vapor permeability is formed.

In the case that the photocuring epoxy adhesive agent of the third embodiment of the invention is the photocuring epoxy adhesive agent of the first embodiment or the second embodiment of the invention, (C) the layered silicate is swelling mica.

If constructed in this manner, then since the dispersibility of the swelling mica is particularly good in, for instance, a resin, the UV transmittance is good, and a synthetic product having stable quality can be readily obtained, and therefore the method is preferred.

In the case that the photocuring epoxy adhesive agent of the fourth embodiment of the invention is the photocuring epoxy adhesive agent of the third embodiment of the invention, (C) the layered silicate is swelling mica containing alkyl ammonium salt between layers.

If constructed in this manner, then the dispersibility of swelling mica containing alkyl ammonium salt between layers to an epoxy monomer or oligomer is excellent, which is preferred.

In the case that the photocuring epoxy adhesive agent of the fifth embodiment of the invention is the photocuring epoxy adhesive agent of the fourth embodiment of the invention, the alkyl ammonium salt contains alkyl ammonium ions having a total carbon number of 1 or more and 60 or less.

If constructed in this manner, then the dispersibility of the alkyl ammonium ions having a total carbon number of 1 or more and 60 or less to the epoxy monomer or oligomer is better, and therefore the method is preferred.

In the case that the photocuring epoxy adhesive agent of the sixth embodiment of the invention is the photocuring epoxy adhesive agent of the fifth embodiment of the invention, the alkyl ammonium salt contains alkyl ammonium ions having a total carbon number of 4 or more and 50 or less.

If constructed in this manner, then the dispersibility of the alkyl ammonium ions having a total carbon number of 4 or more and 50 or less to the epoxy monomer or oligomer is particularly good, which is preferred.

In the case that the photocuring epoxy adhesive agent of the seventh embodiment of the invention is the photocuring epoxy adhesive agent of any one of the first embodiment to the sixth embodiment of the invention, the sharpness of (C) the layered silicate is 100 nm or more and 10 μm or less.

If constructed in this manner, then the dispersibility is particularly good, which is preferred.

In the case that the photocuring epoxy adhesive agent of the eighth embodiment of the invention is the photocuring epoxy adhesive agent of the seventh embodiment of the invention, average particle size of (C) the layered silicate is 10 μm or less.

If constructed in this manner, then the dispersibility is particularly good, which is preferred.

In the case that the photocuring epoxy adhesive agent of the ninth embodiment of the invention is the photocuring epoxy adhesive agent of any one of the first embodiment to the eighth embodiment of the invention, (C) the layered silicate is formed by removing a precipitate•filtered material separated by centrifugal separation or filtration and then performing purification, or dispersing the precipitate•filtered material via an ultrasonic treatment.

If constructed in this manner, then the dispersibility is particularly good, which is preferred.

The resin composition of the tenth embodiment of the invention is obtained by curing the photocuring epoxy adhesive agent of any one of the first embodiment to the ninth embodiment of the invention.

If constructed in this manner, then a resin composition having excellent adhesive strength and resistance to moisture permeation is formed.

The laminate body of the eleventh embodiment of the invention includes: a first adherend body; a second adherend body laminated on the first adherend body; a film containing the resin composition of the tenth embodiment of the invention clamped by the first adherend body and the second adherend body such that the first adherend body and the second adherend body are adhered.

If constructed in this manner, then the first adherend body and the second adherend body can be adhered via a film having excellent adhesive strength and resistance to moisture permeation.

The liquid crystal display of the twelfth embodiment of the invention includes: a first substrate provided with an electrode and an alignment film; a second substrate provided with an electrode and an alignment film; a nematic liquid crystal material disposed between the first substrate and the second substrate; in the resin composition of the tenth embodiment of the invention, the first substrate and the liquid crystal material are adhered, and the second substrate and the liquid crystal material are adhered.

If constructed in this manner, then the resin composition having adhesive properties used in the liquid crystal panel forming the liquid crystal display has sufficient adhesive strength and high resistance to moisture permeation. Therefore, component degradation of the liquid crystal panel and performance degradation of the liquid crystal display caused by water or oxygen permeation in the liquid crystal panel through the resin composition can be inhibited.

The organic electroluminescent (EL) display of the thirteenth embodiment of the invention includes: a first electrode disposed on a substrate; an electroluminescent layer disposed on the first electrode; a second electrode disposed on the electroluminescent layer; a sealing body covering the first electrode, the electroluminescent layer, and the second electrode; and the resin composition of the tenth embodiment of the invention adhesive the substrate and the sealing body.

If constructed in this manner, then the resin composition having adhesive properties used in the organic EL element forming the organic EL display has sufficient adhesive strength and high resistance to moisture permeation. Therefore, component degradation of the constituent elements and performance degradation of the organic EL display caused by water or oxygen permeation in the elements through the resin composition can be inhibited.

The manufacturing method of the resin composition of the fourteenth embodiment of the invention includes the following steps: irradiating UV having a wavelength of 200 nm to 450 nm via a UV intensity of 100 mW/cm² or more to the photocuring epoxy adhesive agent of any one of the first embodiment to the ninth embodiment of the invention.

If constructed in this manner, then the adhesive agent is sufficiently cured, and a resin composition having the strength needed for adhering can be manufactured.

The manufacturing method of the resin composition of the fifteenth embodiment of the invention includes: a step of providing a first adherend body; a step of providing a second adherend body adhered to the first adherend body; a step of disposing the photocuring epoxy adhesive agent of any one of the first embodiment to the ninth embodiment of the invention between the first adherend body and the second adherend body such that the first adherend body and the second adherend body are adhered; and a step of irradiating light to the photocuring epoxy adhesive agent.

If constructed in this manner, then the adhesive agent is sufficiently cured, and a resin composition adhering the first adherend body and the second adherend body can be manufactured.

### Effects of the Invention

The polymerization conversion rate of the photocuring epoxy adhesive agent of the invention at low temperature is excellent, and the photocuring epoxy adhesive agent of the invention has good productivity. Accordingly, the cured product thereof shows excellent adhesive strength and resistance to moisture permeation.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 shows the state of adhering a first adherend body 11a and a second adherend body 11b by curing a photocuring epoxy adhesive agent to obtain a resin composition film 12.

FIG. 2 is a cross-section of a liquid crystal panel 20.

FIG. 3 is a cross-section of an organic EL element 30.

FIG. 4 is a graph of shifting in water vapor permeability of a resin composition (thickness of 15 μm) according to the mica ratio in the resin composition obtained by curing a photocuring epoxy adhesive agent.

FIG. 5 is a graph of particle size distribution of synthetic mica dispersion NTS-5.

FIG. 6 is a graph of particle size distribution of water-swelling mica obtained via centrifugal separation.

FIG. 7 is a graph describing “sharpness”.

### DESCRIPTION OF THE EMBODIMENTS

The present application is based on Japanese Patent Application No. 2013-076249 filed on Apr. 1, 2013 in Japan, and the contents thereof are incorporated into the contents of the present application and are used as a portion of the contents of the present application. The invention can be further understood via the following detailed description. A more specific application scope of the invention is specified in the following detailed description. However, the detailed descriptions and specific examples are ideal implementations of the invention, and are only recited for the purpose of illustration. The reason is that, according to the detailed description, those skilled in the art can understand the various changes and modifications made within the spirit and scope of the invention. The Applicants do not intend to present any embodiment recited to the public, and in the modifications and substitution application, contents in the specification not included in the scope of the claims have the same effect and are also a part of the invention.

In the following, implements of the invention are described in detail with reference to figures. Moreover, the same or similar reference numerals are used for the same or equivalent parts in each figure, and overlapping descriptions are omitted. Moreover, the invention is not limited to the following implementations.

[Photocuring Epoxy Adhesive Agent]

The photocuring epoxy adhesive agent of the first embodiment of the invention is characterized in containing: (A) an epoxy monomer or oligomer, (B) a photo cationic polymerization initiator, and (C) layered silicate. Moreover, (D) other components such as a filler, a modifier, a stabilizer, or an antioxidant can also be included as needed. The photocuring epoxy adhesive agent triggers a polymerization reaction via light irradiation, and curing is performed, and adhering can be performed as a result via the strength needed for adhering.

(A) Epoxy Monomer/Oligomer

(A) the epoxy monomer/or oligomer can include, for instance: an aliphatic epoxy compound, an alicyclic epoxy compound, an aromatic epoxy compound, a novolak epoxy compound, an amine epoxy compound, a glycidyl ester epoxy compound, an aliphatic polyglycidyl ether epoxy compound, a urethane-modified epoxy compound having a urethane bond in the structure, a nitrile-butadiene rubber (NBR)-modified epoxy compound, and oligomers thereof.

Specific examples of the aliphatic epoxy compound include, for instance, a compound having one epoxy group having butyl glycidyl ether, and the compound having two or more epoxy groups can include, for instance: hexanediol diglycidyl ether, tetraethylene glycol diglycidyl ether, trimethylolpropane triglycidyl ether, bisphenol A diglycidyl ether, bisphenol F diglycidyl ether, or a novolak epoxy compound.

The compound having an alicyclic epoxy group can also include, for instance, compounds represented by the following general formula (1) and general formula (2).

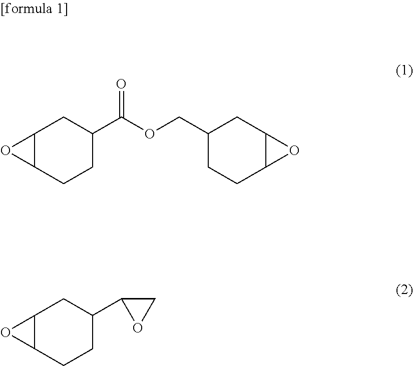

The aromatic epoxy compound can include, for instance: phenyl glycidyl ether, a bisphenol A epoxy compound (such as obtained by reacting bisphenol A and epichlorohydrin), a bisphenol F epoxy compound (such as obtained by reacting bisphenol F and epichlorohydrin), or a bisphenol AD epoxy compound (such as obtained by reacting bisphenol AD and epichlorohydrin). In particular, to obtain the best adhesive time and curability and adhesive properties after UV irradiation, an epoxy resin in liquid state in a standard environment is preferred, and a bisphenol A epoxy resin in liquid state in a standard environment is more preferred.

The epoxy compound and oligomers thereof can be used alone and can also be used in a mixture of two or more. The degree of polymerization of the oligomers of the epoxy compounds can be measured via a method known to those skilled in the art, such as: electron spin resonance (ESR), nuclear magnetic resonance (NMR), or infrared spectroscopy (IR), but the method is not limited thereto.

The epoxy compounds and the oligomers thereof can be synthesized by suitably referencing existing known techniques, and can also be prepared by purchasing commercial products.

(B) Photo Cationic Initiator

(B) the photo cationic initiator is not particularly limited and any (B) photo cationic initiator can be used, as long as it is a compound triggering the cationic polymerization of the resin of (A) the component via light.

Preferred examples of the photo cationic initiator can include, for instance, an onium salt having the structure represented by the following general formula (3). The onium salt is a compound releasing a Lewis acid when a photoreaction is performed.

[R12aR13bR14cR15dW]m⁺[MXn⁺m]m⁻ (3)

In the formula, the cation is an onium ion, W is S, Se, Te, P, As, Sb, Bi, O, I, Br, Cl, or N≡N, R12, R13, R14, and R15 are the same or different organic groups, a, b, c, and d are respectively an integer of 0 to 3, and (a+b+c+d) is equal to ((the valence number of W)+m).

M is a metal or a metalloid of a central atom forming the halide complex [MXn⁺m], such as: B, P, As, Sb, Fe, Sn, Bi, Al, Ca, In, Ti, Zn, Sc, V, Cr, Mn, or Co.

X is, for instance, a halogen atom such as F, Cl, or Br, m is a positive charge of the halide complex ion, and n is the valence number of M.

Specific examples of the onium ions in general formula (3) can include, for instance: diphenyl(4-(phenylthio)phenyl)sulfonium, diphenyl iodonium, 4-methoxy diphenyl iodonium, bis(4-methylphenyl)iodonium, bis(4-tert-butylphenyl)iodonium, bis(dodecylphenyl)iodonium, triphenyl sulfonium, diphenyl-4-thio-phenoxyphenyl sulfonium, bis[4-(diphenyl sulfonium)-phenyl]sulfide, bis[4-(di(4-(2-hydroxyethyl)phenyl)sulfonium)-phenyl]sulfide, and η5-2,4-(cyclopentadienyl)[1,2,3,4,5,6-η-(methylethyl)phenyl]-iron(1+).

Specific examples of the anion in general formula (3) can include, for instance: tetrafluoroborate, hexafluorophosphate, hexafluoroantimonate, hexafluoroarsenate, and hexachoroantimonate.

The anion in general formula (3) substituting the halide complex [MXn⁺m] can also be: perchlorate ion, trifluoromethanesulfonate ion, toluenesulfonate ion, or trinitrotoluene sulfonate ion.

Therefore, the anion in general formula (3) substitutes the halide complex [MXn⁺m], and can also be an aromatic anion. Specific examples can include, for instance: tetra(fluorophenyl)borate, tetra(difluorophenyl)borate, tetra(trifluorophenyl)borate, tetra(tetrafluorophenyl)borate, tetra(pentafluorophenyl)borate, tetra(perfluorophenyl)borate, tetra(trifluoromethylphenyl)borate, or tetra(di(trifluoromethyl)phenyl)borate.

These photo cation initiators can be used alone or in combinations of two or more.

(C) Layered Silicate

(C) The layered silicate can include, for instance, a smectite clay mineral such as montmorillonite, hectorite, saponite, beidellite, stevensite, and nontronite, etc, swelling mica, vermiculite, or halloysite, etc. In particular, at least one selected from the group consisting of montmorillonite, hectorite, swelling mica, and vermiculite is preferred. In particular, since the dispersibility or UV transmittance of swelling mica is particularly good in, for instance, a resin, a synthetic product having stable quality can be readily obtained, which is preferred.

These (C) layered silicate can be used alone or in combinations of two or more.

An exchangeable cation exists between the layers of (C) the layered silicate, such as the so-called exchangeable metal cation, which refers to a metal ion such as sodium or calcium existing on flaky crystal surface of layered silicate. These metal ions have cation exchangeability with a cationic substance, and therefore various substances having cationic properties can be inserted (intercalated) between the crystal layers of the layered silicate.

The cation exchange capacity of (C) the layered silicate is not particularly limited, and a preferred cation exchange capacity is 50 milli equivalent amount/100 g or more and 200 milli equivalent amount/100 g or less. In the case of 50 milli equivalents/100 g, then the amount of the cationic substance intercalated between the crystal layers of the layered silicate is sufficient via cation exchange, and the crystal layers are sufficiently non-polarized in between (hydrophobization). In the case of 200 milli equivalents/100 g or less, the adhesive force between the crystal layers of the layered silicate does not become too strong, and therefore the crystal flakes can be prevented from being too hard to peel off.

(C) The layered silicate has preferably passed a chemical treatment, and the dispersibility thereof in, for instance, a resin has preferably been further improved. The chemical treatment includes, for instance, a cation exchange method using a cationic surfactant. Moreover, the chemical treatment can also suitably adopt other known methods.

Specifically, the cation exchange method using a cationic surfactant includes using a cationic surfactant in advance to perform cation exchange between the layers of layered silicate and performing hydrophobization in advance when a resin composition . . . etc. is obtained using, for instance, a resin. By performing hydrophobization between the layers of layered silicate in advance, the affinity of the layered silicate and, for instance, a resin is increased, such that the layered silicate is more uniformly dispersed in, for instance, the resin.

The cationic surfactant is not particularly limited, and can include, for instance, ammonium chloride or phosphonium salt. In particular, from the viewpoint of sufficient hydrophobization between the crystal layers of the layered silicate, a C₁ to C₆₀ alkyl ammonium salt, aromatic ammonium ion salt, or heterocyclic ammonium ion salt is preferred. C₄ to C₅₀ alkyl ammonium salt is particularly preferred.

As described above, since the dispersibility of the layered silicate (such as swelling mica) containing, for instance, alkyl ammonium salt between layers to an epoxy monomer or oligomer is excellent, layered silicate is preferred.

Moreover, the counter ion can include, for instance: a halogen ion, i.e., fluoride, chloride, bromide, or iodide; and sulfonate, nitrate, hexafluorophosphate, or tetrafluoroborate.

The ammonium salt is not particularly limited, and can include, for instance: tetramethylammonium salt, propyl ammonium salt, butyl ammonium salt, pentyl ammonium salt, hexyl ammonium salt, octyl ammonium salt, bis(2-hydroxyethyl)dimethylammonium salt, tributyl ammonium salt, di(2-hydroxyethyl)ammonium salt, dodecyl ammonium salt, octadecyl ammonium salt, octadecyl methyl ammonium salt, bis(2-hydroxyethyl)octadecyl methyl ammonium salt, octadecyl benzyl dimethyl ammonium salt; a trialkyl ammonium salt such as trimethyl alkyl ammonium salt, triethyl alkyl ammonium salt, tributyl alkyl ammonium salt, dimethyl dialkyl ammonium salt, diethyl dialkyl ammonium salt, dibutyl dialkyl ammonium salt, trialkyl methyl ammonium salt, trialkyl ethyl ammonium salt, or trialkyl butyl ammonium salt; ammonium salt having an aromatic ring such as hexyl ammonium salt, methyl benzyl dialkyl ammonium salt, or dibenzyl dialkyl ammonium salt; ammonium salt derived from aromatic amine such as trimethylphenyl amine; ammonium salt having a heterocyclic ring such as alkylpyridine onium salt or imidazole onium salt; dialkylammonium salt having two polyethylene glycol chains, dialkylammonium salt having two polypropylene glycol chains, trialkyl ammonium salt having one polyethylene glycol chain, or trialkyl ammonium salt having one polypropylene glycol chain. In particular, dodecyl ammonium salt, lauryl trimethyl ammonium salt, lauryl ammonium salt, stearyl trimethyl ammonium salt, stearyl ammonium salt, trioctylmethyl ammonium salt, distearyl dimethyl ammonium salt, or distearyl dibenzyl ammonium salt . . . etc. is preferred.

These ammonium salts can be used alone or in combinations of two or more.

The phosphonium salt is not particularly limited, and can include, for instance: tetrabutylphosphonium salt, trioctyl octadecyl phosphonium salt, tetraoctyl zinc salt, or octadecyl triphenyl phosphonium salt, dodecyl triphenyl phosphonium salt, methyl triphenyl phosphonium salt, lauryl trimethyl phosphonium salt, stearyl trimethyl phosphonium salt, trioctylmethyl phosphonium salt, distearyl dimethyl phosphonium salt, or distearyl dibenzyl phosphonium salt.

These phosphonium salts can be used alone or in combinations of two or more.

The particle size of (C) the layered silicate is not particularly limited, and a preferred particle size is 100 nm or more and 10 μm or less. If (C) the layered silicate within the particle size range has a cumulative pass rate of 80% or more, then impurities are reduced, and the dispersibility of (C) the layer silicate is good. Therefore, the layered structure is uniform, and resistance to moisture permeation is increased.

To evaluate the issue of particle size, “average particle size” is used.

In the present specification, “average particle size” refers to particle size of a cumulative value of 50% in particle size distribution obtained using a laser diffraction-scattering method. The average particle size of (C) the layered silicate is not particularly limited, and a preferred average particle size is 100 nm or more and 10 μm or less. It is shown that by improving the dispersibility of (C) the layered silicate having average particle size, the layered structure is uniform, and resistance to moisture permeation can be increased.

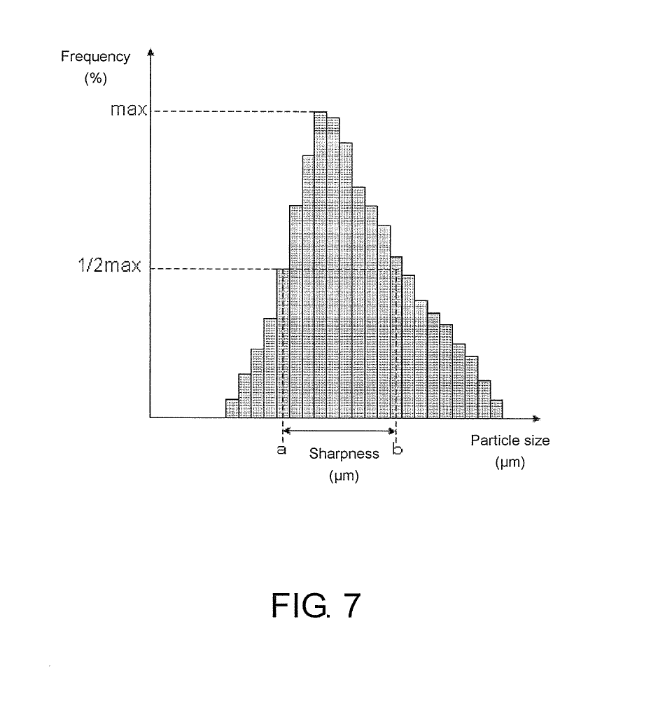

Referring to FIG. 7, the “sharpness” of (C) the layered silicate is defined as follows.

The particle size distribution of particles in one dispersion and the particle size distribution having suitable bin width and number are selected, and the maximum value of the frequency thereof is set as the max.

In the region showing the left side of the bin of max, the central value a is set to meet the particle size width of the smallest bin at a frequency of ≧½ max, and in the region showing the right side of the bin of max, the central value b is set to meet the particle size width of the smallest bin at a frequency of ≧½ max, and “b-a” is defined as the sharpness.

Moreover, in the case of a plurality of particle size distributions having suitable width and number of the bin, the average value of the sharpness in each particle size distribution is used as the sharpness of the particle size distribution thereof.

Regarding sharpness, 20 μm or less is preferred, and 10 μm or less and 100 nm or more is more preferred.

The method of controlling the average particle size of (C) the layered silicate is not particularly limited, and preferred methods include: centrifugal separation, filtration, ultrasonic treatment, ball mill, roll mill, bead mill, and homogenizer. Particularly preferred include methods capable of uniformly controlling average particle size, and can include, for instance, centrifugal separation, filtration, ultrasonic treatment, and homogenizer.

(D) Other Components

In the photocuring epoxy adhesive agent of the present application, (D) other components such as other resin components, fillers, modifiers, stabilizers, or antioxidants can be included without compromising the effect of the invention.

<Silane Coupling Agent>

The photocuring epoxy adhesive agent can also contain a silane coupling agent as needed. The silane coupling agent can include, for instance, a silane compound having a reactive group such as an epoxy group, a carboxyl group, a methacryloyl group, or an isocyanate group.

Specific examples can include, for instance: trimethoxysilyl benzoic acid, γ-methacryloyloxy propyl trimethoxy silane, vinyltriacetoxysilane, vinyl trimethoxysilane, γ-isocyanatopropyltriethoxy silane, γ-glycidoxypropyltrimethoxy silane, or β-(3,4-epoxycyclohexyl)ethyl trimethoxy silane.

These silane coupling agents can be used alone or in combinations of two or more. Based on 100 parts by weight of the photocuring epoxy adhesive agent, the usage amount of the silane coupling agent is preferably 0 parts by weight to 10 parts by weight, more preferably 0.1 parts by weight to 10 parts by weight, and still more preferably 0.3 parts by weight to 8 parts by weight. If such a silane coupling agent is added within the range, then adhesive force is increased, which is preferred.

<Other Resin Components>

The other resin components can include, for instance: polyamide, polyamide-imide, polyurethane, polybutadiene, polychloroprene, polyether, polyester, styrene-butadiene-styrene block copolymer, petroleum resin, xylene resin, ketone resin, cellulose resin, fluorine-based oligomer, silicon-based oligomer, or polysulfide-based oligomer. The components can be used alone, and can also be used in combination. If these resin components are added in suitable amounts as needed, then adhesive force and heat resistance are increased, which is preferred.

<Other Monomer Compounds>

In the photocuring epoxy adhesive agent, other cationic polymerizable compounds of an epoxy monomer/oligomer can also be added. The other cationic polymerizable compounds can include, for instance: an oxolane compound, a cyclic acetal compound, a cyclic lactone compound, a thiirane compound, a thietane compound, a Spiro orthoester compound, a vinyl ether compound, an ethylenically unsaturated compound, a cyclic ether compound, a cyclic thioether compound, or a vinyl compound. These compounds can be used alone, and can also be used in combination. If these cationic polymerizable compounds are added in suitable amounts as needed, then curing is promoted and adhesive force is increased, which is preferred.

<Filler>

The filler can include, for instance: glass beads, styrene-based polymer particles, methacrylate-based polymer particles, vinyl-based polymer particles, or acrylic polymer particles. These fillers can be used alone, and can also be used in combination. If these fillers are added in suitable amounts as needed, then the effect of reducing gas permeability is achieved, which is preferred.

<Modifier>

The modifier can include, for instance: a polymerization initiation auxiliary agent, an anti-aging agent, a leveling agent, a wettability improver, a surfactant, a plasticizer, or a UV absorber. These modifiers can be used alone, and can also be used in combination. If these modifiers are added in suitable amounts as needed, then durability is improved, reliability is improved, and operability is improved, which is preferred.

<Antioxidant>

The antioxidant can include, for instance, a phenol compound. Specifically, the phenol compound can include, for instance: hydroquinone, resorcinol, 2,6-di-tert-butyl-p-cresol, 4,4′-thiobis-(6-tert-butyl-3-methylphenol), 4,4′-butylidenebis-(6-tert-butyl-3-methylphenol), 2,2′-methylenebis-(4-methyl-6-tert-butylphenol), 2,6-di-tert-butyl-4-ethylphenol, 1,3-tris(2-methyl-4-hydroxy-5-tert-butylphenyl)butane, n-octadecyl-3-(3,5-di-tert-butyl-4-hydroxyphenyl)propionate, tetrakis[methylene-3-(3,5-di-tert-butyl-4-hydroxyphenyl)propionate]methane, or triethylene glycol bis[3-(3-tert-butyl-4-hydroxy-5-methylphenyl)propionate]. These phenol compounds can be used alone or in combinations of two or more. If these antioxidants are added in suitable amounts as needed, then oxidation of the components in the photocuring epoxy adhesive agent can be inhibited, which is preferred.

In 100 parts by weight of the photocuring epoxy adhesive agent, the content ratio of (A) the epoxy monomer or oligomer is preferably 5 parts by weight to 60 parts by weight, more preferably 5 parts by weight to 40 parts by weight, and still more preferably 20 parts by weight to 30 parts by weight. If (A) the epoxy monomer or oligomer is 5 parts by weight or more, then photosensitivity and speed curability . . . etc. are excellent, which is preferred.

In 100 parts by weight of the photocuring epoxy adhesive agent, the content ratio of (B) the photo cationic polymerization initiator is preferably 0.1 parts by weight to 10 parts by weight, more preferably 0.3 parts by weight to 4 parts by weight, and still more preferably 0.3 parts by weight to 3 parts by weight. By setting the content ratio of (B) the photo cationic polymerization initiator to 0.1 parts by weight or more, the curing condition of the resin composition can be good, which is preferred. Moreover, from the perspective of preventing the cured photo cationic polymerization initiator from dissolving, 10 parts by weight or less is preferred.

In 100 parts by weight of the photocuring epoxy adhesive agent, the content ratio of (C) the layered silicate is preferably 20 parts by weight to 95 parts by weight, more preferably 40 parts by weight to 80 parts by weight, and still more preferably 50 parts by weight to 70 parts by weight. If (C) the layered silicate is added in the range, then resistance to moisture permeation, adhesive force, and thixotropic properties are improved.

Therefore, the photocuring adhesive agent of the invention preferably contains 5 parts by weight to 60 parts by weight of (A) the epoxy monomer or oligomer, 0.1 parts by weight to 10 parts by weight of (B) the photo cationic initiator, 20 parts by weight to 95 parts by weight of (C) the layered silicate, and 0 parts by weight to 10 parts by weight of (D) the other components (in amounts based on 100 parts by weight of the photocuring epoxy adhesive agent).

In particular, in the photocuring epoxy adhesive agent containing more than 100 parts by weight to 400 parts by weight of (C) the layered silicate based on 100 parts by weight of (A) the epoxy monomer or oligomer, water vapor permeability is extremely low such that the photocuring epoxy adhesive agent has excellent resistance to moisture permeation, which is referred. Specifically, the water vapor permeability of the molded film having a thickness of 15 μm is 1 g/m²/d or less.

Moreover, in the photocuring epoxy adhesive agent, the thickness of the cured resin composition is preferably 3 μm to 50 μm. In the case of 3 μm or more, the photocuring epoxy adhesive agent has sufficient resistance to moisture permeation, and in the case of 50 μm or less, the film thickness is not too thick.

[Preparation of Photocuring Epoxy Adhesive Agent]

The photocuring epoxy adhesive agent of the application is prepared by uniformly mixing each composition. A viscosity range of 0.01 Pa·s to 300 Pa·s can more effectively facilitate coating operation, and the mixing stability of each component is good, which is preferred. The viscosity range is more preferably 0.1 Pa·s to 100 Pa·s. The viscosity can be adjusted only via the mixing ratio of the resin or by adding other components. Moreover, when the viscosity is high, mixing only needs to be performed by using a regular method such as a three-roll machine.

Moreover, in the case of a small amount, a solvent can also be used to mix each composition. In the case that a solvent is used, preferably, each component can be uniformly mixed and dispersed. In the case that a solvent is used, preferably, the solvent of the coated photocuring epoxy adhesive agent is gasified to improve the stability of the shape and the mechanical strength, and then the solvent is cured. The solvent can directly adopt a commercial product, and the used solvent can suitably adopt a conventional solvent to be used alone or used as a mixture.

The photocuring epoxy adhesive agent prepared by the method is only cured by the irradiation of light, and therefore curing can be performed at a low temperature, and the polymerization conversion rate is excellent. Moreover, since the cured resin composition does not consume the solvent, the cured resin composition has the advantage of small volume change. Therefore, the cured resin composition has excellent resistance to moisture permeation. Specifically, as shown in the example, the water vapor permeability of the molded film having a thickness of 15 μm is 1 g/m²/d or less. Therefore, for instance, in the sealing method of the liquid crystal display in which the opposite substrates of the liquid crystal display are adhered using an adhesive agent, an adhesive agent for a liquid crystal display can be used. Moreover, in the sealing method of the electroluminescent display in which the opposite substrates of the electroluminescent display are adhered using an adhesive agent, an adhesive agent for an electroluminescent display can be used. Detailed description is provided below.

As described above, the photocuring epoxy adhesive agent of the application functions as a photocuring adhesive agent. Since the polymerization conversion rate of the cationic polymerizable compound is high, the adhesive agent of the present application has excellent productivity, and adhesive strength and resistance to moisture permeation are excellent. As a result, the adhesive agent of the present application is suitable for, for instance, an adhesive agent for a liquid crystal display or an adhesive agent for an electroluminescent display.

[Resin Composition]

After the prepared photocuring epoxy adhesive agent is coated, curing is performed by irradiation of light to faun a resin composition. A suitable light source here can be any type as long as the light source can cure the adhesive agent within a predetermined operating time. In general, light in the range of UV light and visible light can be irradiated. More specifically, a low-pressure mercury lamp, a high-pressure mercury lamp, a xenon lamp, or a metal halide lamp . . . etc. can be used.

Moreover, in the case that the irradiated light is insufficient, the irradiation light amount can be suitably selected within the range in which the uncured portion of the resin composition does not remain or within the range in which poor adhesive of the uncured portion of the resin composition does not occur, and is generally about 500 mJ/cm² to 3000 mJ/cm². The upper limit of the irradiation amount is not particularly limited, and in the case of an excessive upper limit of the irradiation amount, unnecessary energy is wasted and productivity is reduced, which is therefore not preferred. For instance, UV having a wavelength of 200 nm to 450 nm is preferably irradiated at a UV intensity of 100 mW/cm² or more for 5 seconds to 200 seconds.

[Laminate Body]

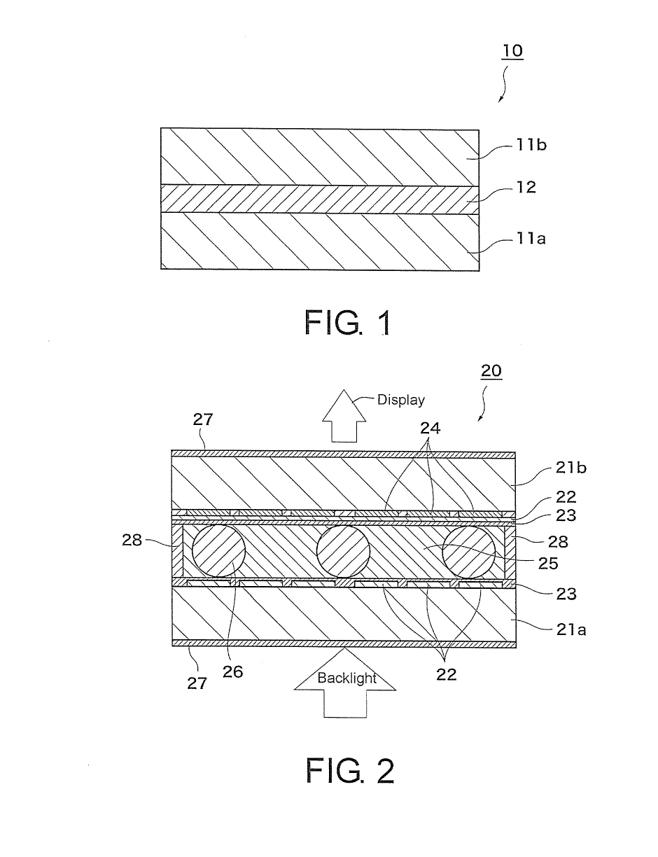

As shown in FIG. 1, the prepared photocuring epoxy adhesive agent is used, such that a first adherend body 11a and a second adherend body 11b are adhered to form a laminate body.

First, a photocuring epoxy adhesive agent is coated on the first adherend body 11a. The coating method is not particularly limited as long as the adhesive agent can be uniformly coated. For instance, a known method such as screen printing or a dispenser can be used for the coating. After coating, light is irradiated on the coating solution such that the second adherend body 11b and the first adherend body 11a are adhered via the coating solution. Alternatively, in the case in which the first adherend body 11a or the second adherend body 11b contains a material allowing light transmission, light can be irradiated on the coating solution via the coating solution after coating after the first adherend body 11a and the second adherend body 11b are adhered. FIG. 1 shows the state of adhesive the first adherend body 11a and the second adherend body 11b by curing the photocuring epoxy adhesive agent to obtain a resin composition film 12.

The first adherend body 11a and the second adherend body 11b include, for instance, a glass plate, a metal plate, or a polymer film.

[Liquid Crystal Display]

Traditionally, the liquid crystal panel (the portion shown in the figure) in the liquid crystal display has a structure in which liquid crystals are clamped via two thin glass plates. The following are exemplarily formed on the surface of the glass plates: an alignment film for twisting liquid crystal molecules into a special shape; a transparent electrode for applying voltage on the liquid crystal layer to control the facing direction of the liquid crystal molecules; and a color filter capable of color display. Moreover, a polarizing plate is attached to the backside and the surface of the liquid crystal panel.

FIG. 2 shows an example of a cross-section of a liquid crystal panel. FIG. 2 shows: a first substrate 21a provided with a transparent electrode 22 used as an electrode and an alignment film 23; a second substrate 21b provided with a transparent electrode 22 used as an electrode and an alignment film 23; and a liquid crystal 25 (such as a nematic liquid crystal material) disposed between the first substrate 21a and the second substrate 21b. Furthermore, FIG. 2 shows that: the photocuring epoxy adhesive agent (a cured resin composition 28) of the present application adheres the first substrate 21a and the liquid crystal 25, and the second substrate 21b and the liquid crystal 25.

For instance, regarding the adhesive of the first substrate 21a and the liquid crystal 25, and the second substrate 21b and the liquid crystal 25, the photocuring epoxy adhesive agent of the present application is first coated on the first substrate 21a and the second substrate 21b. After light is irradiated on the coating solution, the first substrate 21a, the liquid crystal 25, and the second substrate 21b are adhered. After adhesive, light is irradiated on the coating solution to cure the coated adhesive agent. Moreover, the irradiation time of light is generally about 30 seconds to 200 seconds.

[Organic EL Display]

The organic EL element in the organic EL display is a DC-powered light-emitted diode, and is also referred to as an organic light-emitting diode (OLED). Traditionally, the element structure is a clamping structure clamping the organic thin film with electrodes, and in terms of the necessity to remove light, at least one electrode adopts a transparent material such as indium-tin oxide (ITO).

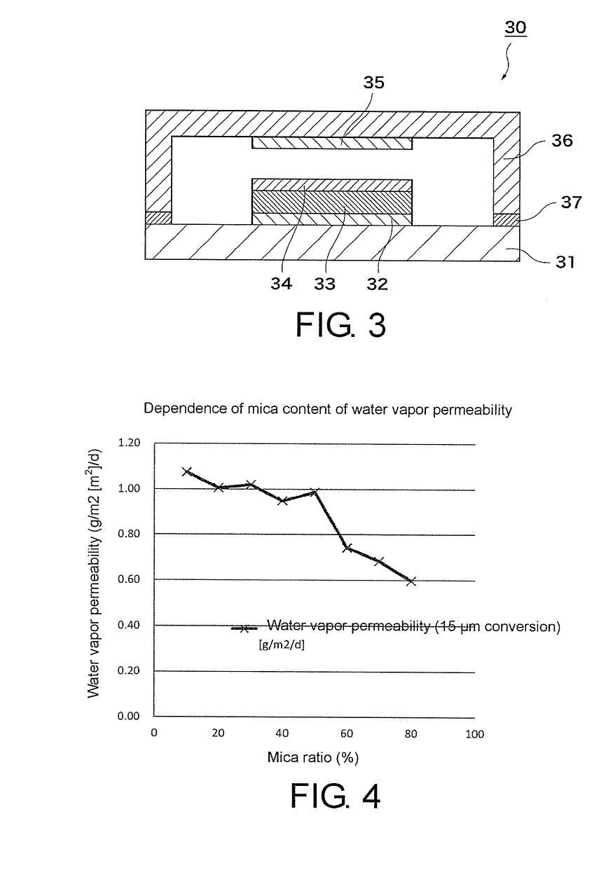

FIG. 3 shows an example of a cross-section of an organic EL element. FIG. 3 shows the following: an anode 32, an electroluminescent layer 33 used as an organic thin film layer, and a cathode 34 are laminated on the surface of a substrate 31 in order, and then a non-gas-permeable protective film 35 is coated on the cathode 34, and then the upper side thereof is sealed via a sealing body 36. In FIG. 3, the photocuring epoxy adhesive agent (a cured resin composition 37) of the present application adheres the substrate 31 and the sealing body 36.

For instance, regarding the adhesive of the substrate 31 and the sealing body 36, the photocuring epoxy adhesive agent of the present application is first coated on the substrate 31. After coating, the substrate 31 and the sealing body 36 are adhered. Then, light is irradiated on the coating solution to cure the coated adhesive agent. Moreover, the irradiation time of light is generally about 30 seconds to 200 seconds.

As described above, the photocuring epoxy adhesive agent of the present application can be used such that the opposite substrates (or the substrate and the sealing body) in the liquid crystal display or the organic EL display are adhered. That is, an example of the liquid crystal display of the invention includes applying the photocuring epoxy adhesive agent of the present application in the adhesive of the opposite substrates of the liquid crystal display. Moreover, an example of the organic EL display of the invention includes applying the photocuring epoxy adhesive agent of the present application in the adhesive of the substrate of the organic EL display and the sealing body.

Accordingly, the manufacturing method of the liquid crystal display or the manufacturing method of the organic EL display of the invention includes applying the photocuring epoxy adhesive agent of the present application such that the opposite substrates (or the substrate and the sealing body) in the liquid crystal display or the organic EL display are adhered. Regarding the adhesive using the photocuring epoxy adhesive agent of the present application, the polymerization conversion rate of the cationic polymerizable compound is high, the productivity thereof is excellent, and a liquid crystal display including a liquid crystal panel having excellent adhesive strength/resistance to moisture permeation or an organic EL display including an organic EL element having excellent adhesive strength/resistance to moisture permeation can be provided.

Moreover, the adherend body used as the adhesive object of the photocuring epoxy adhesive agent of the present application is not limited to the adherend body. In addition to the adhesive of for instance, substrates, the photocuring epoxy adhesive agent of the present application can also be applied in the installation of parts of sophisticated electronic equipment or the fixing of a conducting wire.

### EXAMPLES

Based on the examples, the invention is further described, but the invention is not limited to the following examples.

The water vapor permeability of the thin film made by irradiating light on the photocuring epoxy adhesive agent of the present invention is measured using a water vapor transmission analyzer 7002 (made by Illinois Corporation). The measuring conditions are a temperature of 40° C. and a humidity of 90%.

The film thickness is measured using an MF-501 Digimicro head and a Counter MFC101 (made by Nikon (limited)).

The light transmittance of the thin film having a thickness of about 100 μm made by irradiating light on the glass plates of the photocuring epoxy adhesive agent of the invention is measured using a NDH5000 of Nippon Denshoku Industries (limited) according to JIS K 7361 and using a D65 light source.

The haze of the coating film on the glass substrates made is calculated based on the calculation formula turbidity (haze)=scattered light/total light transmitted light×100 (%) using a NDH5000 of Nippon Denshoku Industries (limited) according to JIS K 7136 according to total light transmittance and diffusivity.

A high-pressure mercury lamp is used as the UV irradiator (made by Ushio Electrical (limited)). A rotation-revolution mixer (ARE250 made by Thinky (limited)) is used to perform mixing-defoaming. A diamond DSC (made by Perkin Elmer) is used to perform thermogravimetric analysis. A high-speed refrigerated centrifuge (Sorvall Biofuge stratos) (made by Kendoro) is used for centrifugal separation. The measurement of thermomechanical analysis (TMA) is performed with TMA/SS6100 made by SII NanoTechnology at a sample size of 10 mm×2 mm.

The particle size control method of swelling mica used in the invention adopts a centrifugal separation method. Specifically, CR22N made by Hitachi Koki (limited) is used to perform centrifugal separation.

The particle size measuring method of swelling mica used in the invention adopts a laser diffraction/scattering particle size distribution measuring apparatus LA-910 made by Horiba Seisakusho (limited).

The components used in the embodiments are as described below.

<Epoxy Monomer>

Celloxide 2021P made by Daicel Chemical (limited)

VG3101L made by Printec Co., Ltd.

JER828 made by Mitsubishi Chemical (limited)

<Photo Cationic Polymerization Initiator>

CPI-210S made by San-Apro (limited)

<Layered Silicate>

Mica dispersion NTS-5 Topy Industries (limited)

<Amine>

Dodecylamine made by Wako Pure Chemical Industries (limited)

<Polyimide Film>

Kapton 300H made by Toray Dupont (limited)

<Solvent>

N,N-dimethylacetamide made by Wako Pure Chemical Industries (limited)

### Example 1

Ultra-pure water (200 g) was added in a 500 mL polypropylene beaker containing synthetic mica dispersion NTS-5 (made by Topy Industries Ltd.) (200 g) to perform precipitation, and ultrasonic wave was irradiated for 30 minutes. Centrifugal separation was performed with a centrifuge under the conditions of 15000 rpm and 20 minutes to separate easily-dispersible water-swelling mica to the water of the upper portion of the precipitation.

Dodecylamine (5.64 g), 12N hydrochloric acid (2.97 ml), and ultra-pure water (100 g) were added in a 1 L separable flask, and the mixture was stirred using a mechanical stirrer until dissolved. Then, a 3% water-swellable mica dispersion (398.9 g) was added, and then the mixture was stirred in an oil bath at 80° C. for 2 hours. After the solid content was filtered and separated via suction filtration, washing was performed with ultra-pure water to obtain the solid content. The separated solid content and ultra-pure water (500 g) were added in the separable flask, and then the mixture was stirred in an oil bath at 80° C. for 2 hours and washed. After the solid content was filtered and separated via suction filtration, washing was performed with ultra-pure water to obtain the solid content. The step is repeated 3 times. The resulting solid content was dried with a vacuum dryer until the weight did not change anymore to form swelling mica.

In a 50 mL glass bottle, swelling mica (1.6 g) and N,N-dimethylacetamide (21 g) were mixed and dispersed by irradiating ultrasonic wave for 5 hours. Then, Celloxide 2021P (made by Daicel Chemical Industries (limited)) (0.4 g) and CPI-210S (made by San-Apro (limited)) (0.004 g) were added, and mixing and defoaming were performed using a rotation revolution mixer. 150 μm was coated on a polyimide film (Kapton 300H) using a Baker applicator, and then in a forced convection dryer, drying was performed at 70° C. for 1 hour. After drying at 100° C. for 4 hours, UV was irradiated under the conditions of a cumulative exposure amount of 500 mJ/cm² using a UV irradiator to obtain a coating film. The coating film thickness was 5.6 μm, and the water vapor permeability was 1.6 [g/m²·day]. Thermogravimetry analysis of the coating film was performed, and the results show no significant peak value before 300° C.

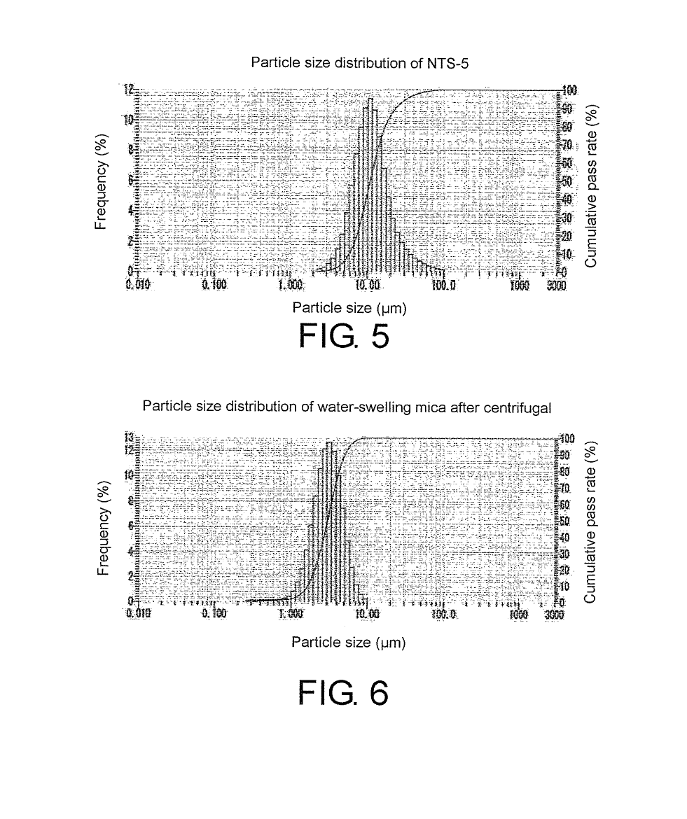

Moreover, the synthetic mica dispersion NTS-5 was measured and the particle size distribution of the water-swelling mica was obtained by centrifugal separation, and the results show that the average particle sizes were respectively 14 μm and 3.3 μm, and the values of sharpness were respectively 12 μm and 3.0 μm. Moreover, FIG. 5 and FIG. 6 show graphs of measured particle size distribution.

The values of average particle size and sharpness of the synthetic mica dispersion NTS-5 and water-swelling mica obtained via centrifugal separation obtained in example 1 are shown in Table 1.

TABLE 1
average particle size and sharpness

| | Particle size distribution | |
|---|---|---|
| | Average particle size (μm) | Sharpness (μm) |
| Synthetic mica dispersion | 14 | 12 |
| NTS-5 | | |
| Water-swelling mica | 3.3 | 3.0 |

### Example 2

In a 50 mL glass bottle, swelling mica (1.4 g) and N,N-dimethylacetamide (18 g) adjusted in the same manner as example 1 were mixed and dispersed by irradiating ultrasonic wave for 5 hours. Then, Celloxide 2021P (made by Daicel Chemical Industries (limited)) (0.6 g) and CPI-210S (0.006 g) were added, and mixing and defoaming were performed using a rotation revolution mixer. 150 μm was coated on a polyimide film (Kapton 300H) using a Baker applicator, and then in a forced convection dryer, drying was performed at 70° C. for 1 hour. After drying at 100° C. for 4 hours, UV was irradiated under the conditions of a cumulative exposure amount of 500 mJ/cm² using a UV irradiator to obtain a coating film. The coating film thickness was 7.3 μm, and the water vapor permeability was 1.4 [g/m²·day].

### Example 3

In a 50 mL glass bottle, swelling mica (1.2 g) and N,N-dimethylacetamide (18 g) adjusted in the same manner as example 1 were mixed and dispersed by irradiating ultrasonic wave for 5 hours. Then, Celloxide 2021P (made by Daicel Chemical Industries (limited)) (0.8 g) and CPI-210S (0.008 g) were added, and mixing and defoaming were performed using a rotation revolution mixer. 150 μm was coated on a polyimide film (Kapton 300H) using a Baker applicator, and then in a forced convection dryer, drying was performed at 70° C. for 1 hour. After drying at 100° C. for 4 hours, UV was irradiated under the conditions of a cumulative exposure amount of 500 mJ/cm2 using a UV irradiator to obtain a coating film. The coating film thickness was 6.5 μm, and the water vapor permeability was 1.7 [g/m²·day].

### Example 4

In a 50 mL glass bottle, swelling mica (1.6 g) and N,N-dimethylacetamide (21 g) adjusted in the same manner as example 1 were mixed and dispersed by irradiating ultrasonic wave for 5 hours. Then, Celloxide 2021P (made by Daicel Chemical Industries (limited)) (0.2 g), VG3101L (made by Printec Co., Ltd.) (0.2 g), and CPI-210S (0.004 g) were added, and mixing and defoaming were performed using a rotation revolution mixer. 150 μm was coated on a polyimide film (Kapton 300H) using a Baker applicator, and then in a forced convection dryer, drying was performed at 70° C. for 1 hour. After drying at 100° C. for 4 hours, UV was irradiated under the conditions of a cumulative exposure amount of 500 mJ/cm² using a UV irradiator to obtain a coating film. The coating film thickness was 5.2 μm, and the water vapor permeability was 1.4 [g/m²·day].

### Example 5

In a 50 mL glass bottle, swelling mica (1.6 g) and N,N-dimethylacetamide (21 g) adjusted in the same manner as example 1 were mixed and dispersed by irradiating ultrasonic wave for 5 hours. Then, Celloxide 2021P (made by Daicel Chemical Industries (limited)) (0.3 g), VG3101L (made by Printec Co., Ltd.) (0.1 g), and CPI-210S (0.004 g) were added, and mixing and defoaming were performed using a rotation revolution mixer. 150 μm was coated on a polyimide film (Kapton 300H) using a Baker applicator, and then in a forced convection dryer, drying was performed at 70° C. for 1 hour. After drying at 100° C. for 4 hours, UV was irradiated under the conditions of a cumulative exposure amount of 500 mJ/cm² using a UV irradiator to obtain a coating film. The coating film thickness was 3.6 μm, and the water vapor permeability was 1.3 [g/m²·day].

### Example 6

In a 50 mL glass bottle, swelling mica (1.6 g) and N,N-dimethylacetamide (21 g) adjusted in the same manner as example 1 were mixed and dispersed by irradiating ultrasonic wave for 5 hours. Then, Celloxide 2021P (made by Daicel Chemical Industries (limited)) (0.2 g), JER828 (made by Mitsubishi Chemical) (0.2 g), and CPI-210S (0.004 g) were added, and mixing and defoaming were performed using a rotation revolution mixer. 150 μm was coated on a polyimide film (Kapton 300H) using a Baker applicator, and then in a forced convection dryer, drying was performed at 70° C. for 1 hour. After drying at 100° C. for 4 hours, UV was irradiated under the conditions of a cumulative exposure amount of 500 mJ/cm² using a UV irradiator to obtain a coating film. The coating film thickness was 4.1 μm, and the water vapor permeability was 1.2 [g/m² ·day].

### Example 7

In a 50 mL glass bottle, swelling mica (1.6 g) and N,N-dimethylacetamide (21 g) adjusted in the same manner as example 1 were mixed and dispersed by irradiating ultrasonic wave for 5 hours. Then, Celloxide 2021P (made by Daicel Chemical Industries (limited)) (0.1 g), JER828 (made by Mitsubishi Chemical) (0.3 g), and CPI-210S (0.004 g) were added, and mixing and defoaming were performed using a rotation revolution mixer. 150 μm was coated on a polyimide film (Kapton 300H) using a Baker applicator, and then in a forced convection dryer, drying was performed at 70° C. for 1 hour. After drying at 100° C. for 4 hours, UV was irradiated under the conditions of a cumulative exposure amount of 500 mJ/cm² using a UV irradiator to obtain a coating film. The coating film thickness was 6.1 μm, and the water vapor permeability was 0.9 [g/m²·day].

### Example 8

In a 50 mL glass bottle, swelling mica (1.6 g) and N,N-dimethylacetamide (21 g) adjusted in the same manner as example 1 were mixed and dispersed by irradiating ultrasonic wave for 5 hours. Then, Celloxide 2021P (made by Daicel Chemical Industries (limited)) (0.2 g), JER806 (made by Mitsubishi Chemical) (0.2 g), and CPI-210S (0.004 g) were added, and mixing and defoaming were performed using a rotation revolution mixer. 150 μm was coated on a polyimide film (Kapton 300H) using a Baker applicator, and then in a forced convection dryer, drying was performed at 70° C. for 1 hour. After drying at 100° C. for 4 hours, UV was irradiated under the conditions of a cumulative exposure amount of 500 mJ/cm² using a UV irradiator to obtain a coating film. The coating film thickness was 6.5 μm, and the water vapor permeability was 1.0 [g/m²·day].

### Example 9

In a 50 mL glass bottle, swelling mica (1.6 g) and N,N-dimethylacetamide (21 g) adjusted in the same manner as example 1 were mixed and dispersed by irradiating ultrasonic wave for 5 hours. Then, Celloxide 2021P (made by Daicel Chemical Industries (limited)) (0.1 g), JER806 (made by Mitsubishi Chemical) (0.3 g), and CPI-210S (0.004 g) were added, and mixing and defoaming were performed using a rotation revolution mixer. 150 μm was coated on a polyimide film (Kapton 300H) using a Baker applicator, and then in a forced convection dryer, drying was performed at 70° C. for 1 hour. After drying at 100° C. for 4 hours, UV was irradiated under the conditions of a cumulative exposure amount of 500 mJ/cm² using a UV irradiator to obtain a coating film. The coating film thickness was 5.4 μm, and the water vapor permeability was 1.0 [g/m²·day].

### Example 10

In a 50 mL glass bottle, swelling mica (1.6 g) and N,N-dimethylacetamide (21 g) adjusted in the same manner as example 1 were mixed and dispersed by irradiating ultrasonic wave for 5 hours. Then, Celloxide 2021P (made by Daicel Chemical Industries (limited)) (0.3 g), JER806 (made by Mitsubishi Chemical) (0.1 g), and CPI-210S (0.004 g) were added, and mixing and defoaming were performed using a rotation revolution mixer. 150 μm was coated on a polyimide film (Kapton 300H) using a Baker applicator, and then in a forced convection dryer, drying was performed at 70° C. for 1 hour. After drying at 100° C. for 4 hours, UV was irradiated under the conditions of a cumulative exposure amount of 500 mJ/cm² using a UV irradiator to obtain a coating film. The coating film thickness was 3.9 μm, and the water vapor permeability was 1.4 [g/m²·day].

### Example 11

In a 50 mL glass bottle, STN-5 (26.7 g), Celloxide 2021P (made by Daicel Chemical Industries (limited)) (0.4 g), and CPI-210S (0.004 g) used in example 1 were added, and mixing and defoaming were performed using a rotation revolution mixer. 150 μm was coated on a polyimide film (Kapton 300H) using a Baker applicator, and then in a forced convection dryer, drying was performed at 70° C. for 1 hour. After drying at 100° C. for 4 hours, UV was irradiated under the conditions of a cumulative exposure amount of 500 mJ/cm² using a UV irradiator to obtain a coating film. The coating film thickness was 11 μm, and the water vapor permeability was 1.6 [g/m²·day].

### Comparative Example 1

In a 50 mL glass bottle, N,N-dimethylacetamide (21 g), Celloxide 2021P (made by Daicel Chemical Industries (limited)) (2 g), and CPI-210S (0.02 g) were mixed, and mixing and defoaming were performed using a rotation revolution mixer. 150 μm was coated on a polyimide film (Kapton 300H) using a Baker applicator, and then in a forced convection dryer, drying was performed at 70° C. for 1 hour. After drying at 100° C. for 4 hours, UV was irradiated under the conditions of a cumulative exposure amount of 500 mJ/cm² using a UV irradiator to obtain a coating film. The coating film thickness was 4.6 μm, and the water vapor permeability was 42 [g/m²·day].

The measured values of water vapor permeability and the conversion values for film thicknesses at 15 μm or less of example 1 to example 11 and comparative example 1 are shown in Table 2.

TABLE 2
water vapor permeability

| | | | | | | | Water vapor |
|---|---|---|---|---|---|---|---|
| | | | Coating | | | | permeability |
| | Water-swelling | | film | Water vapor | Total light | | (15 μm |
| | mica | STN-5 | thickness | permeability | transmittance | Haze | conversion) |
| | amount | amount | [μm] | [g/m²/d] | (%) | (%) | [g/m²/d] |
| Example 1 | 80 | 0 | 5.6 | 1.6 | 88.9 | 17.2 | 0.60 |
| Example 2 | 70 | 0 | 7.32 | 1.4 | 89.3 | 20.2 | 0.68 |
| Example 3 | 60 | 0 | 6.54 | 1.7 | 89.7 | 26.3 | 0.74 |
| Example 4 | 80 | 0 | 5.2 | 1.4 | 89.7 | 28.3 | 0.49 |
| Example 5 | 80 | 0 | 3.62 | 2.1 | 89.7 | 22.5 | 0.51 |
| Example 6 | 80 | 0 | 4.14 | 1.2 | 89.4 | 25.3 | 0.33 |
| Example 7 | 80 | 0 | 6.06 | 0.9 | 88.6 | 25.9 | 0.36 |
| Example 8 | 80 | 0 | 6.54 | 1.0 | 89.1 | 32.5 | 0.44 |
| Example 9 | 80 | 0 | 5.36 | 1.0 | 89.6 | 25.9 | 0.36 |
| Example 10 | 80 | 0 | 3.9 | 1.4 | 88.4 | 29.3 | 0.36 |
| Example 11 | 0 | 80 | 11 | 1.6 | 88.4 | 27.2 | 2.18 |
| Comparative | 0 | 0 | 4.64 | 42 | 98.2 | 3.4 | 12.99 |
| example 1 | | | | | | | |

As shown in Table 2, in example 1 to example 10, the water vapor permeability values in the case of film thickness converted to 15 μm are all 1 g/m²/day or less, thus showing high resistance to moisture permeation. Moreover, in example 11, the water vapor permeability in the case of film thickness converted to 15 μm is 2.18 g/m²/day, which also shows high resistance to moisture permeation.

FIG. 4 shows changes in water vapor permeability (g/m²/day) based on mica content (wt %). It can be known from FIG. 4 that, if the mica ratio exceeds 50 wt %, then the water vapor permeability is 1 g/m²/day or less, thus showing extremely high resistance to moisture permeation. In other words, if the resin composition is formed by more than 100 parts by weight to 400 parts by weight of (C) the layered silicate based on 100 parts by weight of (A) the epoxy monomer or oligomer, then the resistance to moisture permeation of the resin composition is particularly good.

Moreover, the results of thin-film measured coefficient of linear expansion (TMA) of example 1 to example 10 are all 30 ppm or less.

All literature containing the published objects, patent applications, and patents referenced in the present specification respectively and specifically show each literature and are incorporated by reference. In addition, all of the contents thereof are referenced and incorporated into the present specification with the same limit described in the present specification.

If not particularly indicated in the present specification or not significantly contradicting to the specification, any term used in relation to the description (in particular relating to the following claims) and the use of similar terms of the invention are to be interpreted as singular and plural. If not particularly described, Willis such as “including”, “having”, “containing”, and “comprising” are interpreted as open-ended terms (i.e., the meaning of “although contains . . . but not limited to”). If not particularly indicated in the present specification, then the detailed description of numeric ranges in the present specification only functions as superficial description, and the superficial description is used to respectively mention each value only in the range, and each value is incorporated in the specification by respectively providing examples in the present specification. If not particularly indicated in the present specification or not significantly contradicting to the specification, all of the methods described in the present specification can be performed in any suitable order. If not particularly claimed, all of the examples or exemplarily wording (such as “etc.”) used in the present specification are only intended to more sufficiently describe the invention, and do not limit the scope of the invention. The wordings in the specification do not represent indispensable objects in the examples of the invention or elements not recited in the claims.

In the present specification, to implement the invention, the most preferred configurations known to the Inventors are included, and preferred embodiments of the invention are described. To those skilled in the art, modifications to these preferred embodiments are clear after reading the description. The Inventors expect skilled persons to suitably apply the modifications described above and implement the invention with methods other than the ones specifically described in the present specification by default. Therefore, the invention includes amendments of recited content in the accompanying claims and all of the equivalents in the present specification in a manner in accordance with the law. As a result, any combination of elements in any variation not particularly indicated in the present specification or not significantly contradicting to the specification is included in the invention.

### DESCRIPTION OF THE LABELS

10 laminate body

11a first adherend body

11b second adherend body

12 film obtained by resin composition film

20 liquid crystal panel

21a first substrate

21b second substrate

22 transparent electrode

23 alignment film

24 color filter

25 liquid crystal

26 spacer

27 polarizer

28 resin composition

30 organic EL element

31 substrate

32 anode

33 electroluminescent layer

34 cathode

35 non-gas-permeable protective film

36 sealing body

37 resin composition

1. A photocuring epoxy adhesive agent, containing:
(A) an epoxy monomer or an oligomer;
(B) a photo cationic polymerization initiator; and
(C) layered silicate.

2. The photocuring epoxy adhesive agent of claim 1, containing 100 parts by weight of (A) the epoxy monomer or oligomer and more than 100 parts by weight to 400 parts by weight of (C) the layered silicate.

3. The photocuring epoxy adhesive agent of claim 1, wherein (C) the layered silicate is swelling mica.

4. The photocuring epoxy adhesive agent of claim 3, wherein (C) the layered silicate is swelling mica containing alkyl ammonium salt between layers.

5. The photocuring epoxy adhesive agent of claim 4, wherein the alkyl ammonium salt contains alkyl ammonium ions having a total carbon number of 1 or more and 60 or less.

6. The photocuring epoxy adhesive agent of claim 5, wherein the alkyl ammonium salt contains alkyl ammonium ions having a total carbon number of 4 or more and 50 or less.

7. The photocuring epoxy adhesive agent of claim 1, wherein a sharpness of (C) the layered silicate is 100 nm or more and 10 μm or less.

8. The photocuring epoxy adhesive agent of claim 7, wherein an average particle size of (C) the layered silicate is 10 μm or less.

9. The photocuring epoxy adhesive agent of claim 1, wherein (C) the layered silicate is (C) a layered silicate for which a precipitate•filtered product separated by a centrifuge or separated by filtering is removed for purification, or dispersed via an ultrasonic treatment.

10. A resin composition obtained by curing the photocuring epoxy adhesive agent of claim 1.

11. A laminate body, comprising:
a first adherend body;
a second adherend body laminated on the first adherend body; and
a film containing the resin composition of claim 10 clamped by the first adherend body and the second adherend body, and adhering the first adherend body and the second adherend body.

12. A liquid crystal display, comprising:
a first substrate provided with an electrode and an alignment film;
a second substrate provided with an electrode and an alignment film;
a nematic liquid crystal material disposed between the first substrate and the second substrate; and
the resin composition of claim 10 adhering the first substrate and the liquid crystal material, and the second substrate and the liquid crystal material.

13. An organic electroluminescent display, comprising:
a first electrode disposed on the substrate;
an electroluminescent layer disposed on the first electrode;
a second electrode disposed on the electroluminescent layer;
a sealing body covering the first electrode, the electroluminescent layer, and the second electrode; and
the resin composition of claim 10 adhering the substrate and the sealing body.

14. A manufacturing method of a resin composition, comprising: a step of irradiating the photocuring epoxy adhesive agent of claim 1 with UV having a wavelength of 200 nm to 450 nm at a UV intensity of 100 mW/cm2 or more.

15. A manufacturing method of a laminate body, comprising:
a step of providing a first adherend body;
a step of providing a second adherend body adhered to the first adherend body;
a step of disposing the photocuring epoxy adhesive agent of claim 1 between the first adherend body and the second adherend body such that the first adherend body and the second adherend body are adhered; and
a step of irradiating light on the photocuring epoxy adhesive agent.pound is a precursor of Au.
